(19) United States
(12) Patent Application Publication
(10) Pub. No.: US 2009/0250853 A1
(43) Pub. Date: Oct. 8, 2009

(54) TORSION RESILIENT ELEMENT FOR HANGING MICROMECHANICAL ELEMENTS WHICH CAN BE DEFLECTED

(75) Inventors: Alexander Wolter, Dresden (DE); Christian Drabe, Dresden (DE); Thomas Klose, Dresden (DE)

Correspondence Address: BARNES & THORNBURG LLP, 11 SOUTH MERIDIAN, INDIANAPOLIS, IN, 46204, US

(73) Assignee: FRAUNHOFER-GESELLSCHAFT ZUR FORDERUNG DER ANGEWAND

(21) Appl. No.: 12/297,878

(22) PCT Filed: Apr. 24, 2006
(86) PCT No.: PCT/DE06/00746

§ 371 Date: Jan. 21, 2009

(51) Int. Cl. B81B 3/00

(52) U.S. Cl. 267/154

(57) ABSTRACT

The invention relates to torsion spring elements for the suspension of deflectable micromechanical elements such as reflecting elements pivotable around a rotational axis. It is therefore the object of the invention to provide torsion spring elements for suspensions of deflectable micromechanical elements which can achieve improved properties in operation with respect to known spring elements. Torsion spring elements in accordance with the invention are made so that they have a changing geometrical design in the direction of their longitudinal axis and thereby have non-linear spring characteristics. The longitudinal axis is in this respect aligned between a clamping or support and the deflectable micromechanical element which is held by at least one torsion spring element. In this respect, a torsion spring element in accordance with the invention can have a straight-line region, which is aligned in the direction of the longitudinal axis, and a fork/branching at at least one end face into which the straight-line region merges.

The invention relates to torsion spring elements for the suspension of deflectable micromechanical elements such as reflecting elements pivotable around a rotational axis. In this connection, the pivoting can take place in oscillating manner between two reversal points with preset rotational angle amounts. The drive of this pivot movement can take place electrostatically or while utilizing a different physical principle in a manner known per se.

To keep the energy required for the drive as low as possible, such systems are frequently operated while observing resonant conditions. The natural resonance of such a system must be taken note of in this respect. This depends on a plurality of parameters. In addition to the dead weight, the spring characteristics of spring elements and the respective deflection must also be taken into account. With a constant driving power, when the resonant frequency in the drive is taken into account, a much larger deflection can be achieved than is the case in driving frequency ranges differing therefrom. Further problems applying in this respect will be pointed out in the following.

Spring elements having linear spring characteristics are used for the suspension of such deflectable micromechanical elements. This is also the case in systems which use the drive concept also known as “out-of-plane electrode comb” which is described by H. Schenk in “Ein neuartiger Mikroaktuator zur ein- und zweidimensionalen Ablenkung von Licht” [An innovative microactuator for the one-dimensional and two-dimensional deflection of light]; Dissertation 2000; Gerhard-Mercator University, Duisburg.

Hysteresis effects occur and it must also be noted that normally only drive frequencies can be used for the observation of resonant conditions which are above the resonant frequency (natural frequency). Such an operation cannot be achieved starting from smaller drive frequencies. If the resonant frequency is not reached, this state collapses and can only be started again at a drive frequency considerably above the resonant frequency (as a rule four times the resonant frequency). Permanent operation with resonant conditions takes place at a drive frequency which corresponds to double the resonant frequency.

An exact regulation is required for this purpose in which the phase must also be taken into account.

The maximum possible deflection of a micromechanical element can, however, frequently not be utilized since there is a risk on operation in the proximity of the resonant frequency that the oscillating deflection already collapses on low fluctuations of the drive frequency. The stability of the maximum deflection (amplitude) must also be noted which depends to a very large degree on the respective drive frequency in the proximity of the resonant frequency. Small changes in the drive frequency in this range thus result in considerably changing deflections.

In such systems, which should be operated under resonant conditions, the endeavor is made to avoid influences on the resonant frequency which result in its change in operation. This applies to the influence of the respective deflection and to the spring characteristics of spring elements used which should have linear spring characteristics at least in the working range. A change in the resonant frequency namely also occurs in dependence on the respective deflection with spring characteristics different therefrom, which results in a displacement in the direction of a smaller resonant frequency with degressive spring characteristics and in the direction of a higher resonant frequency with progressive spring characteristics with an increasing deflection.

The effect known as “pull-in” should also be taken into account which disadvantageously has the result that a maximum possible deflection cannot be utilized to reliably avoid mechanical damage to such a system.

It is therefore the object of the invention to provide torsion spring elements for suspensions of deflectable micromechanical elements which can achieve improved properties in operation with respect to known spring elements.

This object is solved in accordance with the invention by torsion spring elements made in accordance with claim 1. Advantageous embodiments and further developments of the invention can be achieved using features designated in the subordinate claims.

Torsion spring elements in accordance with the invention are made so that they have a changing geometrical design in the direction of their longitudinal axis and thereby have non-linear spring characteristics.

The longitudinal axis is in this respect aligned between a clamping or support and the deflectable micromechanical element which is held by at least one torsion spring element.

In this respect, a torsion spring element in accordance with the invention can have a straight-line region, which is aligned in the direction of the longitudinal axis, and a fork/branching into which the straight-line region merges. Such a torsion spring element can then at least approximately form the shape of a “Y”.

One or more fork(s)/branching(s) present at such a torsion spring element can be made in V shape or U shape with limbs. The limbs can be connected at their outer end faces to the deflectable element or to a support/clamping.

At least two limbs can be made at a fork/branching. However, more than two limbs can also be present. These limbs can in turn be connected via a part made, for example, in the form of a transverse web.

The limbs of a fork/branching can be made in a straight-line. They can also be aligned parallel to one another and to the longitudinal axis.

Limbs of a fork/branching can also be made in curved form.

A fork/branching formed at a torsion spring element should be made symmetrical with respect to the longitudinal axis.

A possible embodiment of a torsion spring element in accordance with the invention can be made at at least one end face in the form of a triangle adjoining a region made in a straight line.

Forks/branchings formed at end faces of a torsion spring element can have designs differing from one another and can optionally be connected directly to one another so that no region aligned in a straight line in the direction of the longitudinal axis has to be present at such a torsion spring element.

Forks/branchings at a torsion spring element can, however, also have a different length and/or number of limbs in the direction of the longitudinal axis. This can be achieved by lengths of limbs of the forks/branchings differing from one another.

A region connected to a fork/branching or running out in this manner can be made so that it has a changing section modulus in the longitudinal direction. This can be achieved e.g. in a simple manner by a changing cross-section. The cross-sectional surface can be varied in this respect.

The change in the section modulus can preferably be chosen to be continuous in the direction of the longitudinal axis.

In this respect, the section modulus can increase in the direction of the longitudinal axis up to the reaching of a maximum and can then reduce again in the following.

A branching between two regions made in a straight line can also be formed at a torsion spring element in accordance with the invention with limbs having mutually different alignments being present at such a branching. The limbs of such a branching can be aligned orthogonally, in parallel and/or in an obliquely inclined angle with respect to the longitudinal axis.

Torsion spring elements having spring characteristics adapted to an application can be made available by a correspondingly adapted design and dimensioning. In this respect, spring characteristics can be preset in which a specific spring force can be achieved in dependence on the respective deflection. Spring characteristics of torsion spring elements in accordance with the invention can thus be present in which a degressive behavior occurs, and then a progressive behavior with larger deflections. Lower driving forces are thus necessary at the start and with a smaller deflection than is the case with larger deflections. The restoring forces of deflected torsion spring elements also behave in this manner. Accordingly, the restoring forces are smaller in the proximity of the rest position or center position; with, however, no linear relationships being present, as with linear spring characteristics, with respect to the respective deflection and the respective forces at least regionally in the deflection.

The torsion spring elements quasi represent a “series connection” by an embodiment in accordance with the invention although it is actually a single element. The gradation of the spring characteristics of a torsion spring element in accordance with the invention can take place a plurality of times and the increase in spring forces in dependence on the respective deflection can be changed a plurality of times.

In a number of application cases, disadvantages of spring elements having linear spring characteristics can be avoided or reduced.

The torsion spring elements in accordance with the invention can be made analog to conventional spring elements, with only the corresponding design being taken into account and such that the manufacturing effort and/or cost does not have to be increased.

The torsion spring elements in accordance with the invention can be present at reflective elements such as micro-mirrors which can be used with the most varied scanners.

A use is also possible with devices for data output such as with laser displays, laser printers, laser exposure devices or similar.

There is, however also the possibility of providing the torsion spring elements in deflectable elements in sensors such as pressure sensors, viscosity sensors or accelerometers.

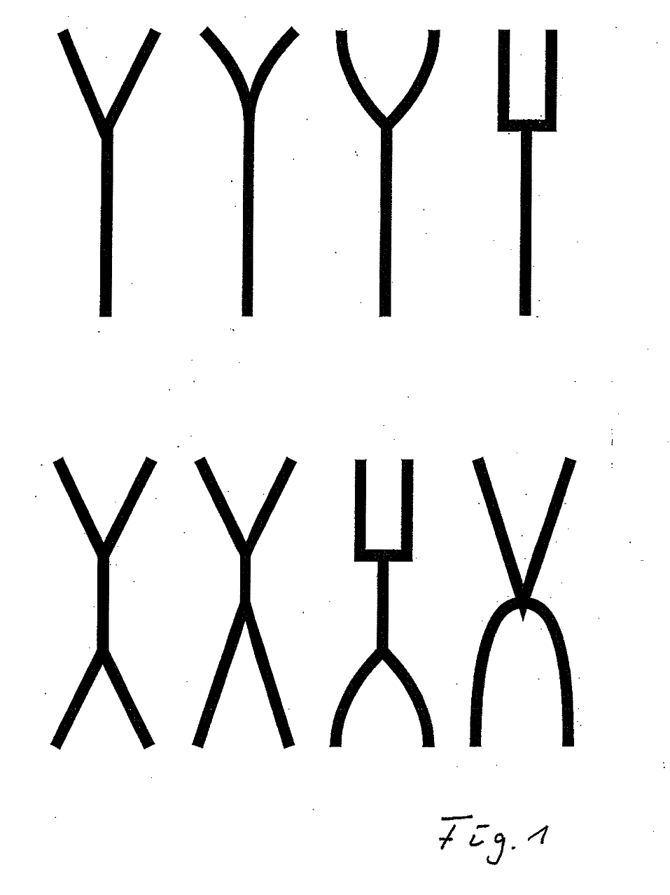

The invention should be explained illustratively in the following with the help of examples shown in FIGS. 1 to 7.

Eight examples for possible embodiments of examples of torsion spring elements in accordance with the invention are thus shown in FIG. 1.

In this respect, a region aligned in a straight line in the direction of the longitudinal axis is present in all of them with the exception of the example shown at the right in the lower row. The examples shown in the upper row have a fork/branching at an end face which is made in V shape or also in U shape.

The examples shown in the lower row have forks/branches at both end faces which can each also have different designs or be varied with respect to their length in the direction of the longitudinal axis.

The example shown at the far right in the lower row is formed from two forks/branchings directly connected to one another, with one being made in U shape and the other in V shape.

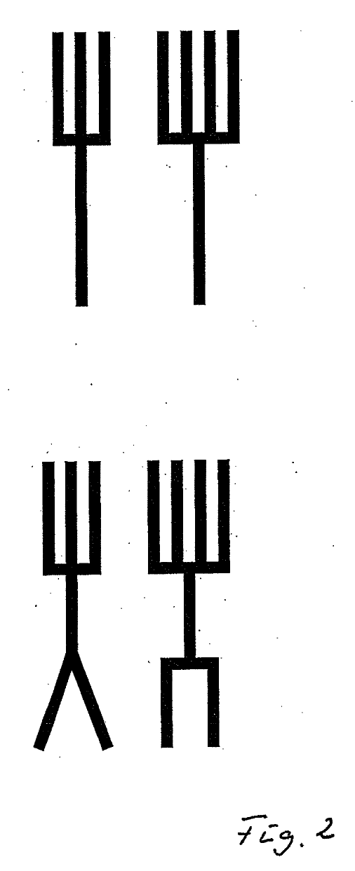

Four further examples should be illustrated with FIG. 2. In the two upper examples, a fork/branching having more than two limbs adjoins a region made in a straight line at an end face.

In the two examples shown at the bottom, they have been provided with a V-shaped or U-shaped fork/branching additionally having two limbs at the oppositely disposed end face.

For the examples explained here, a respectively equal cross-sectional surface was taken into account for all parts and regions. This is, however, not the case in the two examples shown in FIG. 3. A part of a torsion spring element is in this respect made in the longitudinal direction by a continuous change in the cross-sectional surface in the direction of the longitudinal axis. The section modulus thereby also changes correspondingly, which influences the spring characteristics with differing deflection.

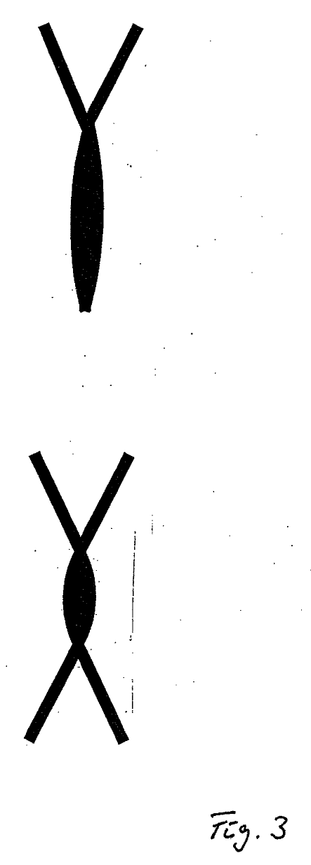

FIG. 4 shows an example in which a branching in the form of a triangle adjoins a region made in a straight line at an end face.

In the example shown in FIG. 5, two respective limbs, which form a pair, are present at two oppositely disposed end faces. The limb length of the two pairs differs in this respect so that the angle the two limbs of a pair include is also of a different size.

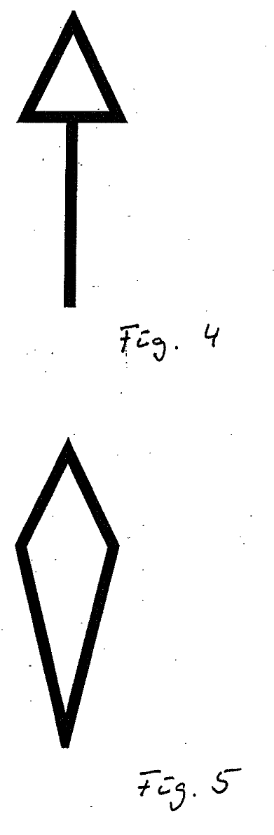

In the examples shown in FIGS. 6 and 7, a branching is present which is arranged between and connected to two regions made in a straight line. A plurality of limbs are again present at the branching and their alignment differs from one another.

In the example in accordance with FIG. 7, a V-shaped fork/branching is additionally present at an end face.

1. A torsion spring element for the suspension of deflectable micromechanical elements which is held at a suspension and is connected to a micromechanical element, the torsion spring element having a geometrical design changing in the direction of its longitudinal axis providing a non-linear spring characteristic.

2. A torsion spring element in accordance with claim 1 including a straight-line region aligned in the direction of the longitudinal axis, the straight-line region having at least one end face, and at least one of a fork and a branching at the at least one end face.

3. A torsion spring element in accordance with claim 2 wherein the at least one of a fork and a branching is made in at least one of a V shape and a U shape.

4. A torsion spring element in accordance with claim 2 wherein the at least one of a fork and a branching includes at least two limbs.

5. A torsion spring element in accordance claim 2 wherein a region is formed in the shape of a triangle at the at least one end face.

6. A torsion spring element in accordance with claim 2 including two differently configured ones of at least one of a fork and a branching connected to one another.

7. A torsion spring element in accordance with claim 6 wherein the at least two differently configured ones of at least one of a fork and a branching at a torsion spring element a comprise two differently configured ones of at least one of a fork and a branching having at least one of different lengths and different numbers of limbs in the direction of the longitudinal axis.

8. A torsion spring element in accordance with claim 2 wherein a region connected to the at least one of a fork and a branching has a section modulus changing in the longitudinal direction.

9. A torsion spring element in accordance with claim 8 wherein the section modulus changes continuously.

10. A torsion spring element in accordance with claim 8 wherein the section modulus increases up to the reaching of a maximum and subsequently reduces in the longitudinal direction.

11. A torsion spring element in accordance with claim 2 wherein the at least one of a fork and a branching is made in at least one of a V-shaped region and a U-shaped the at least one of a V-shaped region and a U-shaped region including limbs differing in length from one another in the longitudinal direction.

12. A torsion spring element in accordance with claim 1 which is symmetrical orthogonally to the longitudinal axis.

13. A torsion spring element in accordance with claim 2 wherein the at least one of a fork and a branching includes limbs, each of which is configured in a straight line.

14. A torsion spring element in accordance with claim 2 wherein the at least one of a fork and a branching includes limbs, each of which is curved.

15. A torsion spring element in accordance with claim 2 wherein the at least one of a fork and a branching comprises a plurality of limbs extending in mutually different directions formed between two regions made in a straight line.

16. A torsion spring element in accordance with claim 15 wherein the limbs are at least one of orthogonal to the longitudinal axis, parallel to the longitudinal axis and at an obliquely inclined angle with respect to the longitudinal axis.

17. A torsion spring element in accordance with claim 2 wherein the at least one of a fork and a branching is symmetrical with respect to the longitudinal axis.

18. A torsion spring element in accordance with claim 1 configured to provide a degressive spring characteristic evolution with smaller deflections and a progressive spring characteristic evolution as the deflections increase.
